(19) United States
(12) Patent Application Publication
(10) Pub. No.: US 2026/0103086 A1
(43) Pub. Date: Apr. 16, 2026

(54) INVERTER-BASED POSITION SENSOR FOR A TRACTION MOTOR OF A VEHICLE

(71) Applicant: GM GLOBAL TECHNOLOGY OPERATIONS LLC, DETROIT, MI (US)

(72) Inventors: Muhammad Ahsan Zahid, Troy, MI (US); Ajay Mehta, Auburn Hills, MI (US); Yilun Luo, Ann Arbor, MI (US); Khorshed Mohammed Alam, Canton, MI (US); Mazharul Chowdhury, Canton, MI (US); Edward W. Mellet, Rochester Hills, MI (US)

(21) Appl. No.: 18/915,857

(22) Filed: Oct. 15, 2024

(51) Int. Cl. B60L 15/20; H05K 1/18

(52) U.S. Cl. CPC B60L 15/20; H05K 1/181; B60L 2240/421; B60L 2240/423; H05K 2201/05; H05K 2201/1009; H05K 2201/10196

(57) ABSTRACT

Examples described herein provide a vehicle that includes a drive unit. The drive unit includes a printed circuit board (PCB) having a coil assembly. The drive unit further includes a rotor assembly connected to a shaft, the shaft having a target. The drive unit further includes circuitry electrically coupled to the coil assembly, the circuitry transmitting an electromagnetic field from the coil assembly to the target on the shaft, receiving a reflected electromagnetic field at the coil assembly from the target on the shaft, and determining a position of the shaft based at least in part on the reflected electromagnetic field.

The subject disclosure relates to vehicles, and in particular to an inverter-based position sensor for a traction motor of a vehicle.

Modern vehicles (e.g., a car, a motorcycle, a boat, or any other type of automobile) may be equipped one or more drive units for providing propulsion. A drive unit in a vehicle refers to the assembly that includes various components, such as the motor, transmission, and differential, that is responsible for converting energy from the motor (whether internal combustion or electric) into motion, which propels the vehicle. In electric vehicles (EVs), a traction motor is often part of the drive unit. The traction motor is an electric motor specifically designed to provide the torque for driving wheels of the vehicle.

### SUMMARY

In one embodiment, a vehicle is provided. The vehicle includes a drive unit. The drive unit includes a printed circuit board (PCB) having a coil assembly. The drive unit further includes a rotor assembly connected to a shaft, the shaft having a target. The drive unit further includes circuitry electrically coupled to the coil assembly, the circuitry transmitting an electromagnetic field from the coil assembly to the target on the shaft, receiving a reflected electromagnetic field at the coil assembly from the target on the shaft, and determining a position of the shaft based at least in part on the reflected electromagnetic field.

In addition to one or more of the features described herein, or as an alternative, further embodiments of the vehicle may include that the coil assembly includes a transmitting coil and receiving coils.

In addition to one or more of the features described herein, or as an alternative, further embodiments of the vehicle may include that the receiving coils include a receiving sine coil and a receiving cosine coil.

In addition to one or more of the features described herein, or as an alternative, further embodiments of the vehicle may include that the transmitting coil and the receiving coils are disposed on a first layer of the PCB and a second layer of the PCB.

In addition to one or more of the features described herein, or as an alternative, further embodiments of the vehicle may include that the coil assembly includes a first transmitting coil associated with a first set of receiving coils, and a second transmitting coil associated with a second set of receiving coils.

In addition to one or more of the features described herein, or as an alternative, further embodiments of the vehicle may include that the first transmitting coil and the first set of receiving coils are disposed on a first layer of the PCB and a second layer of the PCB, and wherein the second transmitting coil and the second set of receiving coils are disposed on a third layer of the PCB and a fourth layer of the PCB.

In addition to one or more of the features described herein, or as an alternative, further embodiments of the vehicle may include that the circuitry includes an application-specific integrated circuit.

In addition to one or more of the features described herein, or as an alternative, further embodiments of the vehicle may include that the circuitry is disposed on the PCB.

In addition to one or more of the features described herein, or as an alternative, further embodiments of the vehicle may include that the circuitry is disposed on a second PCB, the second PCB being a flexible PCB being substantially circular and defining an interior portion, wherein the target is positioned within the interior portion.

In another embodiment, a drive unit for a vehicle is provided. The drive unit includes a printed circuit board (PCB) having a position sensor. The drive unit further includes a rotor assembly connected to a shaft, the shaft having a target. The drive unit further includes circuitry electrically coupled to the position sensor, the circuitry determining a position of the shaft using the target.

In addition to one or more of the features described herein, or as an alternative, further embodiments of the drive unit may include that the target includes a disk affixed to an end of the shaft, wherein the disk includes a first side affixed to the end of the shaft, a second side, and an edge between a first circumference of the first side and a second circumference of the second side, wherein the edge includes a channel having a varying width based at least in part on a number of poles of the drive unit.

In addition to one or more of the features described herein, or as an alternative, further embodiments of the drive unit may include that the circuitry determines the position of the shaft based at least in part on the channel.

In addition to one or more of the features described herein, or as an alternative, further embodiments of the drive unit may include that the target includes a magnet having a north pole and a south pole.

In addition to one or more of the features described herein, or as an alternative, further embodiments of the drive unit may include that the circuitry includes the position of the shaft based at least in part on the north pole and the south pole.

In addition to one or more of the features described herein, or as an alternative, further embodiments of the drive unit may include that the position sensor is a magnetoresistive sensor.

In addition to one or more of the features described herein, or as an alternative, further embodiments of the drive unit may include that the position sensor is an anisotropic magnetoresistance effect sensor.

In addition to one or more of the features described herein, or as an alternative, further embodiments of the drive unit may include that the position sensor is a giant magnetoresistance effect sensor.

In addition to one or more of the features described herein, or as an alternative, further embodiments of the drive unit may include that the position sensor is a tunnel magnetoresistance effect sensor.

In addition to one or more of the features described herein, or as an alternative, further embodiments of the drive unit may include that the position sensor is a circular vertical hall effect sensor.

In another embodiment a printed circuit board associated with a drive unit of a vehicle and being oriented substantially perpendicular to an axial direction of a shaft of the drive unit is provided. The printed circuit board includes a microcontroller, a first application-specific integrated circuit, a second application-specific integrated circuit, and a plurality of layers. A first layer of the plurality of layers and a second layer of the plurality of layers include a first transmitting coil and a first set of receiving coils. A third layer of the plurality of layers and a fourth layer of the plurality of layers include a second transmitting coil and a second set of receiving coils. The first application-specific integrated circuit transmits a first electromagnetic field from the first transmitting coil to a target on the shaft, receives a first reflected electromagnetic field at the first set of receiving coils from the target on the shaft, and determines a first position of the shaft based at least in part on the first reflected electromagnetic field. The second application-specific integrated circuit transmits a second electromagnetic field from the second transmitting coil to the target on the shaft, receives a second reflected electromagnetic field at the second set of receiving coils from the target on the shaft, and determines a second position of the shaft based at least in part on the second reflected electromagnetic field. The microcontroller determines a third position of the shaft based at least in part on the first position and the second position.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 schematically illustrates a vehicle having a traction motor and a position sensor assembly according to an embodiment;

FIG. 2A schematically illustrates a detailed view of a position sensor assembly according to an embodiment;

FIG. 2B schematically illustrates a detailed view of a position sensor assembly according to an embodiment;

FIG. 3 schematically illustrates a detailed view of components within the traction motor according to an embodiment;

FIG. 4A schematically illustrates arrangements of the coil assembly according to various embodiments;

FIG. 4B schematically illustrates arrangements of the coil assembly according to various embodiments;

FIG. 5A schematically illustrates layers of a printed circuit board for the arrangements shown in FIG. 4A according to various embodiments;

FIG. 5B schematically illustrates layers of a printed circuit board for the arrangements shown in FIG. 4B according to various embodiments;

FIG. 6 schematically illustrates a detailed view of components within the traction motor according to an embodiment;

FIG. 7 schematically illustrates a detailed view of components within the traction motor according to an embodiment; and

FIG. 8 schematically illustrates a detailed view of components within the traction motor according to an embodiment.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

One or more embodiments described herein relates to an inverter-based position sensor for a traction motor of a vehicle.

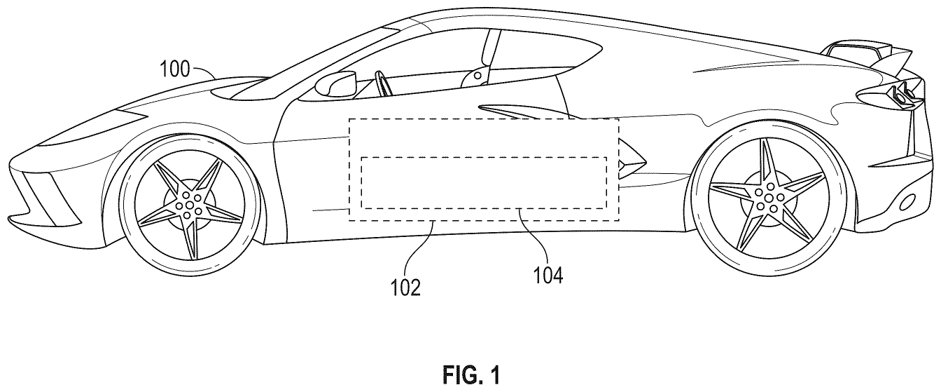

FIG. 1 is an illustration of a vehicle 100 having a traction motor 102 and a position sensor assembly 104, according to an embodiment. The vehicle 100 can be a car, a truck, a van, a bus, a motorcycle, a boat, or any other type of automobile. According to an embodiment, the vehicle 100 includes an internal combustion engine fueled by gasoline, diesel, or the like. According to another embodiment, the vehicle 100 is a hybrid electric vehicle partially or wholly powered by electrical power. According to another embodiment, the vehicle 100 is an electric vehicle powered by electrical power. According to one or more embodiments, the vehicle 100 is an autonomous or semi-autonomous vehicle. An autonomous vehicle is a vehicle that has self-driving capabilities.

According to one or more embodiments, the vehicle 100 includes the traction motor 102. As described herein, vehicles may use traction motors, such as the traction motor 102, to provide propulsion for a vehicle. Traction motors use position sensors to provide precise control of motor speed and torque by accurately detecting the rotor's position, enabling efficient commutation and synchronization in multi-motor systems. The use of position sensors enhances the responsiveness and efficiency of the traction motor, supporting advanced driving features, such as traction control and stability control. Position sensors are useful for optimizing the performance and reliability of electric vehicles.

Current propulsion systems for vehicles often rely on position sensors that utilize targets fabricated from laminated steel, such as resolvers. Such approaches, while effective, present several challenges. The complex wound sensing structures required for these approaches occupy significant volume, leading to packaging difficulties within the traction motor. Further, resolvers use laminated steel targets, which increase weight, size, and complexity. The packaging challenges posed by resolvers can limit the flexibility in design and integration within various motor topologies, making optimization of the layout and performance of the drive unit difficult. Additionally, the intricate nature of these components can complicate the manufacturing and assembly processes, potentially increasing production time and complexity.

One or more embodiments described herein addresses these shortcomings by integrating a position sensor assembly 104 into a low-voltage printed circuit board (PCB) of an inverter of the traction motor 102. This approach provides a more compact and efficient design, reducing the overall volume and complexity of the position feedback mechanism used in traction motors. By providing an approach with fewer components, easier packaging integration for different motor topologies is provided. One or more embodiments enhances the functionality and reliability of the traction motor while maintaining a streamlined and efficient design.

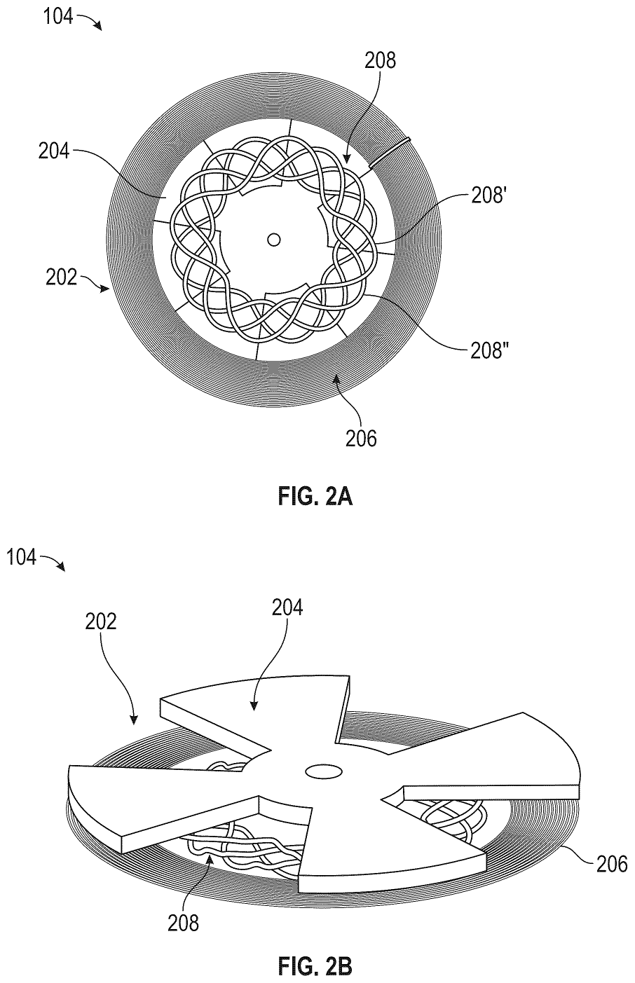

FIGS. 2A and 2B, which are now described together, illustrate a detailed view of a position sensor assembly 104 integrated into a low-voltage PCB of an inverter of the traction motor 102 according to an embodiment. The position sensor assembly 104 includes a coil assembly 202 and a target 204. The coil assembly 202 includes a transmitting coil 206 and receiving coils 208. The receiving coils 208 include a receiving sine coil 208′ and a receiving cosine coil 208″. It should be appreciated that the coil assembly 202 may include other numbers of coils than shown as further described herein. For example, in an embodiment, the coil assembly can include two transmitter coils and four receiver coils.

The transmitting coil 206 is responsible for generating an electromagnetic field that interacts with the target 204. The target 204, which is connected to the shaft of the traction motor, reflects the electromagnetic field back to the receiving coils 208 as the shaft, and therefore also the target 204, spins. The receiving sine coil 208′ and the receiving cosine coil 208″ detect the reflected signals, which are then used to determine the precise position of the rotor within the traction motor.

This configuration allows for accurate position sensing of the shaft while minimizing the volume and complexity of the position feedback mechanism.

By integrating the position sensor assembly 104 into the inverter's low-voltage PCB, the overall design is more compact and efficient, facilitating easier packaging integration for different motor topologies. This approach enhances the functionality and reliability of the traction motor 102 while maintaining a streamlined and efficient design.

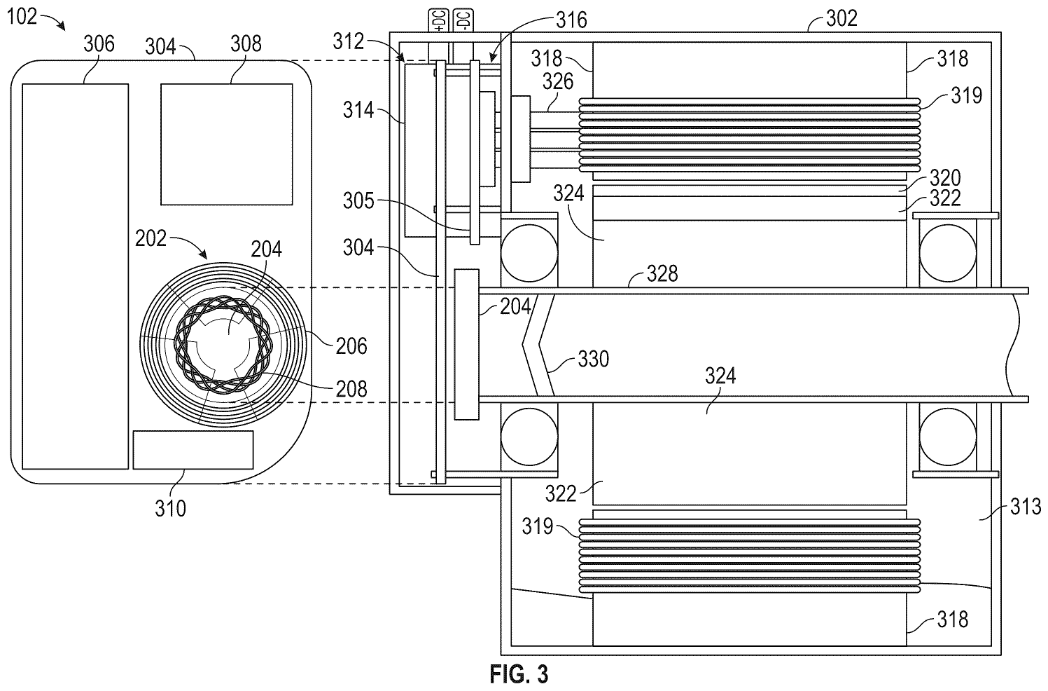

FIG. 3 illustrates a detailed view of components within the traction motor 102 according to an embodiment. The traction motor 102 includes a housing 302, a PCB 304, a PCB 305, dry area 312, wet area 313, direct current (DC) capacitor 314, coolant block 316, stator 318, windings 319, rotor assembly 320, magnets 322, rotor laminations 324, stator winding busbars 326, shaft 328, and shaft ingress separator 330. The traction motor 102 also includes the coil assembly 202 and target 204.

The housing 302 is part of the traction motor 102 and encloses the components of the traction motor 102, including the PCB 304, the gate drive 308, the position sensor ASIC 310, the dry area 312, the DC capacitor 314, the coolant block 316, the stator 318, the wet area 313, the windings 319, the rotor assembly 320, the magnets 322, the rotor laminations 324, the stator winding busbars 326, the shaft 328, and the shaft ingress separator 330. The housing 302 provides structural support and protection for the components within the traction motor 102.

The target 204 is connected to the shaft 328 within the traction motor 102. The target 204 interacts with the coil assembly 202 to facilitate position sensing. The target 204 can be a disk affixed to an end of the shaft 328, the disk having a first side affixed to the end of the shaft 328, a second side, and an edge between a first circumference of the first side and a second circumference of the second side.

The transmitting coils (Tx coils) 206 are part of the coil assembly 202 and are embedded into the PCB 304. The Tx coils 206 are responsible for transmitting an electromagnetic field to the target 204 on the shaft 328. The Tx coils 206 can be co-planar on the same layer of the PCB 304 or stacked on different layers of the PCB 304. The Tx coils 206 can be associated with receiving coils (Rx coils) 208.

The Rx coils 208 are also part of the coil assembly 202 and are embedded into the PCB 304. The Rx coils 208 receive a return electromagnetic field from the target 204 on the shaft 328. The Rx coils 208 can include the receiving coil 208′ and the receiving coil 208″ as shown in FIGS. 2A and 2B. The Rx coils 208 can be co-planar on the same layer of the PCB 304 or stacked on different layers of the PCB 304. According to one or more embodiments, the receiving coil 208′ may be a receiving sine coil, and the receiving coil 208″ may be a receiving cosine coil. It should be appreciated that more than two receiving coils may be implemented in various embodiments.

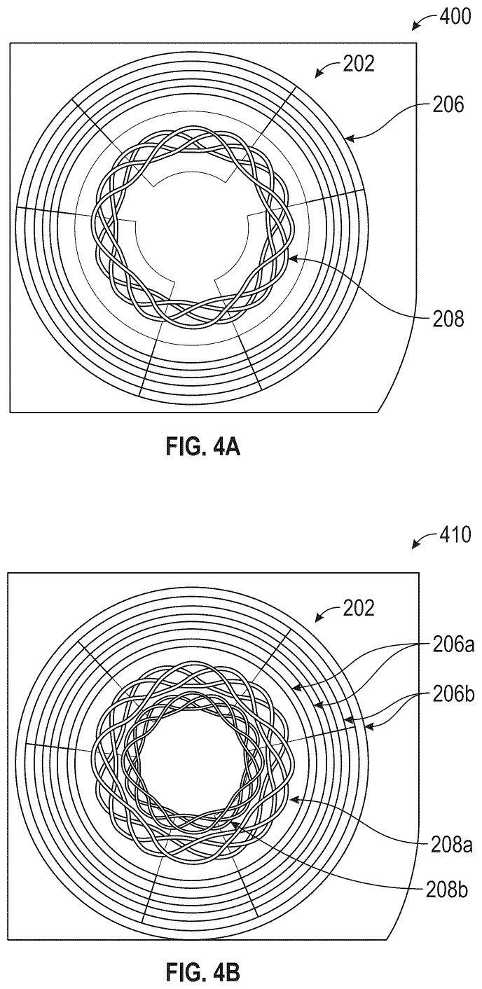

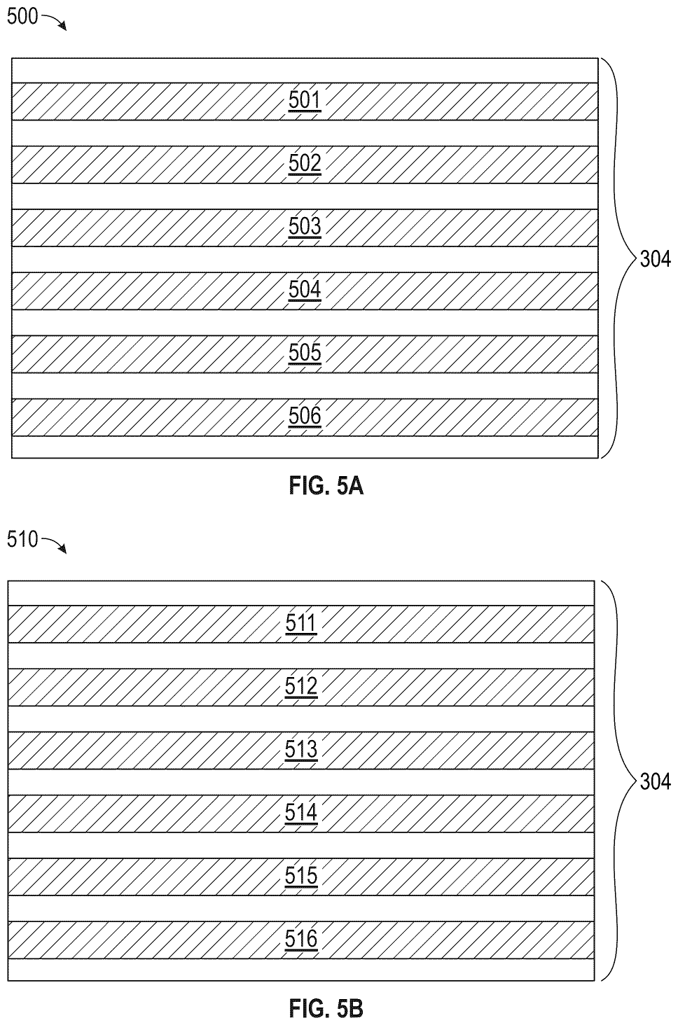

The PCB 304 is a component of the traction motor 102, which includes the coil assembly 202 (including the Tx coils 206 and Rx coils 208), a microcontroller 306, a gate drive 308, and a position sensor ASIC 310. It should be appreciated that, in other embodiments, some of the components shown on the PCB 304 can be separated onto another PCB (e.g., a “daughter board”). For example, the coil assembly 202 can be on a daughter board if the PCB 304 is not arranged in the housing 302 in such a way as to cause the coil assembly 202 to align with the target 204. According to one or more embodiments, the PCB 304 is oriented substantially perpendicular to an axial direction of the shaft 328 of the traction motor 102. According to one or more embodiments, the PCB 304 includes multiple layers. For example, a first layer and a second layer can include the transmitting coil 206 and the receiving coils 208; other layers can include additional components, such as additional transmitting and receiving coils as described with reference to FIGS. 4B and 5B. The PCB 304 also houses the position sensor ASIC 310 and the microcontroller 306, which are responsible for controlling the electromagnetic field generated by the coil assembly 202 and processing the return electromagnetic field received by the coil assembly 202.

The microcontroller 306 is part of the traction motor 102 and is responsible for processing the signals from the coil assembly 202 and/or the position sensor ASIC 310. The microcontroller 306 determines the position of the shaft 328 based on the return signals from the coil assembly 202 and provides control signals to the gate drive 308 to ensure precise operation of the traction motor 102.

The gate drive 308 is part of the traction motor 102 and is responsible for controlling the power electronics that drive the traction motor 102. The gate drive 308 amplifies control signals to switch power transistors (e.g., metal-oxide-semiconductor field-effect transistors (MOSFETs) or insulated-gate bipolar transistors (IGBTs)) on and off in power electronics circuits, ensuring efficient and accurate operation of these devices. The gate drive 308 interfaces with the PCB 304 and the position sensor ASIC 310, which controls the Tx coil 206 and processes the return electromagnet field detected by the Rx coils 208 to determine a precise position of the shaft 328.

According to one or more embodiments, the position sensor ASIC 310 is an application-specific integrated circuit that is electrically coupled to the coil assembly 202. In other embodiments, the position sensor ASIC 310 can implement any suitable circuit architecture other than an ASIC, such as a field-programmable gate array (FPGA), general-purpose microcontroller, digital signal processor, system-on-chip, and/or the like, including combinations and/or multiples thereof. The position sensor ASIC 310 causes the coil assembly 202 to transmit an electromagnetic field the target 204 on the shaft 328, receives a return signal at the coil assembly 202 from the target 204 on the shaft 328, and determines a position of the shaft 328 based at least in part on the return signal. The position sensor ASIC 310 can be placed relatively close to the Tx coils 206 on the PCB 304 to minimize trace lengths and improve signal integrity.

The PCB 305 is another PCB within the traction motor 102. The PCB 305 can house additional circuitry and components useful for the operation of the traction motor 102.

In this embodiment, the dry area 312 within the traction motor 102 houses the power electronics and position sensing components, including the PCB 304 and the coil assembly 202. The dry area 312 is separated from the wet area 313, which contains lubricants and cooling components, ensuring that the sensitive electronic components are protected from exposure to fluids.

The DC capacitor 314 is part of the traction motor 102 and is responsible for smoothing the DC voltage supplied to the power electronics. The DC capacitor 314 is located within the dry area 312 and is electrically connected to the PCB 304 and to the windings 319 of the stator 318 via the stator winding busbars 326.

The coolant block 316 is part of the traction motor 102 and is responsible for cooling the power electronics and other components within the dry area 312. The coolant block 316 interfaces with the wet area 313 or externally to ensure efficient heat dissipation and maintain optimal operating temperatures for the electronic components.

The stator 318 is part of the traction motor 102 and contains the windings 319 that generate the magnetic field necessary for the operation of the traction motor. The stator 318 is located within the wet area 313 and is cooled by the lubricants and cooling components within the wet area 313. The windings 319 are part of the stator 318 and are responsible for generating the magnetic field that interacts with the rotor assembly 320 to produce torque. The windings 319 are located within the wet area 313 and are cooled by the lubricants and cooling components within the wet area 313.

The rotor assembly 320 is part of the traction motor 102 and is connected to the shaft 328. The rotor assembly 320 contains the magnets 322 and the rotor laminations 324, which interact with the magnetic field generated by the windings 319 to produce torque. The rotor assembly 320 is located within the wet area 313 and is cooled by the lubricants and cooling components within the wet area 313. The magnets 322 are part of the rotor assembly 320 and are responsible for interacting with the magnetic field generated by the windings 319 to produce torque. The magnets 322 are located within the wet area 313 and are cooled by the lubricants and cooling components within the wet area 313. The rotor laminations 324 are part of the rotor assembly 320 and are responsible for reducing eddy current losses and improving the efficiency of the traction motor. The rotor laminations 324 are located within the wet area 313 and are cooled by the lubricants and cooling components within the wet area 313.

The stator winding busbars 326 are part of the traction motor 102 and are responsible for delivering power to the windings 319 of the stator 318. For example, if the traction motor 102 is a three-phase motor, power is supplied through three alternating current (AC) phases that are substantially 120 degrees out of phase with respect to one another, creating a rotating magnetic field in the stator 318. This rotating magnetic field induces a current in the rotor assembly 320, causing the rotor assembly 320 to turn and generate mechanical power which is delivered by the shaft 328. The three-phase power system ensures smooth and continuous torque, making it highly efficient for motor operation of the traction motor 102. According to one or more embodiments, the stator winding busbars 326 are electrically connected to the PCB 304, which can control the power delivered by the stator winding busbars 326, ensuring precise control of the operation of the traction motor 102 based on the position feedback from the position sensor assembly 104.

The shaft 328 is part of the traction motor 102 and is connected to the rotor assembly 320. The shaft 328 interacts with the target 204 and the coil assembly 202 to facilitate position sensing. For example, the target 204 rotates as the shaft 328 rotates, and the position of the shaft is detected as described herein using the position sensor assembly 104. The shaft 328 delivers mechanical force to whatever object(s) are connected to the shaft (e.g., a wheel of the vehicle 100) as the shaft rotates. The shaft 328 is located within the wet area 313 and is cooled by the lubricants and cooling components within the wet area 313.

The shaft ingress separator 330 is part of the traction motor 102 and is responsible for reducing or preventing contaminants, such as dust, dirt, or liquids, from entering the area where the shaft 328 passes through a housing or enclosure. The shaft ingress separator 330 is located around the shaft 328 and provides a seal.

FIG. 4A illustrates one possible arrangement 400 of the coil assembly 202. In this configuration, the Tx coils 206 and the Rx coils 208 are co-planar on two layers of the PCB 304 (see FIG. 5A). For example, FIG. 5A shows layers 500 of the PCB 304. Layers 501, 502, 503, and 504 are free layers (meaning these layers do not have any Tx coils or Rx coils), while the Tx coils 206 and the Rx coils 208 are disposed in the layers 505 and 506. The Tx coils 206 are responsible for generating an electromagnetic field that interacts with the target 204 on the shaft 328. The Rx coils 208 detect the return electromagnetic field from the target 204, which is used to determine the position of the shaft 328.

FIG. 4B illustrates another possible arrangement 410 of the coil assembly 202. In this configuration, two transmitting coils (the Tx coil 206a and the Tx coil 206b) are shown, along with two sets of receiving coils (the Rx coils 208a and the Rx coils 208b). The Tx coil 206a is associated with one set of receiving coils (e.g., the Rx coils 208a), and the Tx coil 206b is associated with the other set of receiving coils (e.g., the Rx coils 208b). For example, FIG. 5B shows layers 510 of the PCB 304. Layers 511 and 512 are free layers; Tx coils 206b and Rx coils 208b are disposed in the layers 513 and 514, and the Tx coils 206a and the Rx coils 208b are disposed on the layers 515 and 516. This stacked arrangement allows for redundant position sensing, enhancing the reliability and accuracy of the position feedback mechanism.

It should be appreciated that the embodiment of FIGS. 4B and 5B provide redundancy and/or improved sensing relative to the embodiment of FIGS. 4A and 5A. For example, the configuration of FIGS. 4B and 5B provides the ability to perform redundant measurements to allow for automotive safety integrity level (ASIL) level D (ASIL-D) certification for rotor position sensing. For example, the Tx coil 206 and the Rx coils 208 maintain both types of ASIL-D redundancy.

In some embodiments, two separate sets of coils (e.g., FIGS. 4B and 5B) can be implemented along with two separate ASICs (e.g., two of the position sensor ASICs 310). According to one or more embodiments, the two sets of coils can be placed directly on top of one another (e.g., using two layers of the PCB) or offset from one another (e.g., using four layers of the PCB, such as shown in FIG. 5B). In such an embodiment, each set of coils has its own ASIC responsible for excitation and receiving. The two ASICs send the sensing information to a single microcontroller (e.g., the microcontroller 306) for redundant feedback in case one coil or ASIC fails.

In some embodiments, two separate ASICs (e.g., two of the position sensor ASICs 310) can be implemented with a single set of coils (e.g., FIGS. 4A and 5A). That is, the redundant two sets of coils can be substituted for a single set of coils with each connected to two ASICs. If one of the ASICs fails, the other ASIC can still successfully determine the position of the shaft 328.

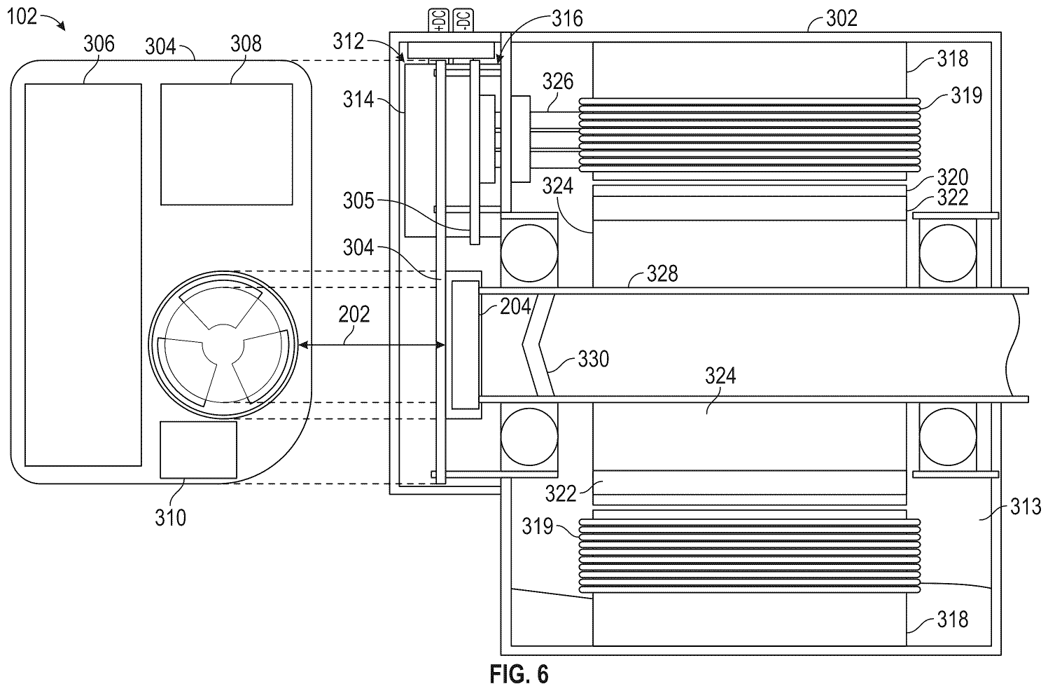

FIG. 6 illustrates a detailed view of components within the traction motor 102 according to an embodiment. As shown in FIG. 6, in this embodiment, the traction motor 102 implements the position sensor assembly 104 of FIGS. 2A and 2B in a radial orientation. More particularly, the coil assembly 202 surrounds the target 204 as shown. For example, the coil assembly 202 can be implemented in a flexible PCB that surrounds the target 204. According to one or more embodiments, a two-layer flex PCB containing the Tx coils 206 and Rx coils 208 can be electrically connected to the PCB 304 to detect the shaft 328 mounted target 204 and report the position back to the microcontroller 306. As the shaft 328 rotates (and thus the target 204 rotates), the coil assembly 202 surrounding the rotating target 204 emits and detects electromagnetic waves as described herein to determine the position of the shaft 328.

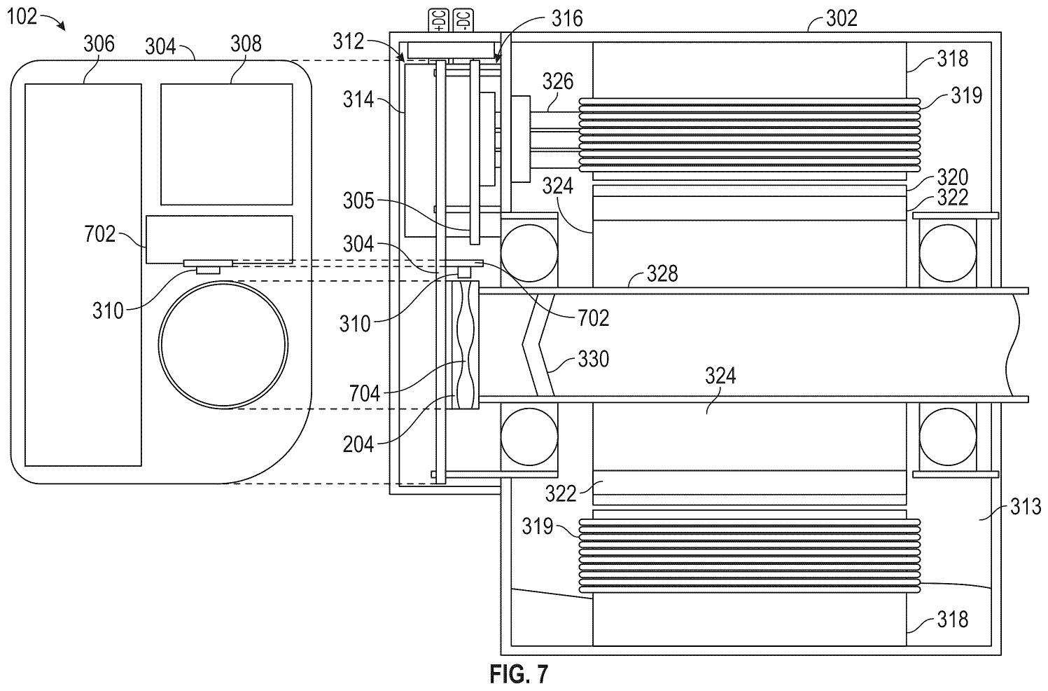

FIG. 7 illustrates a detailed view of components within the traction motor 102 according to an embodiment. As shown in FIG. 7, in this embodiment, the traction motor 102 implements a position sensing PCB 702 that includes the position sensor ASIC 310. This is another example of a radial orientation; however, in this embodiment, the target 204 has a channel 704, which provides a varying airgap grove feature on the shaft, that can be detected by the position sensor ASIC 310. The position sensing PCB 702 is positioned substantially co-planar with the axis of the shaft 328 such that the position sensing PCB 702 is substantially parallel to an edge of the target 204. According to one or more embodiments, the edge of the target 204 includes a channel 704 having a varying width. According to one or more embodiments, the channel 704 can be machined or otherwise caused to be recessed into the target 204. According to one or more embodiments, the channel 704 can extend outwardly from the target 204. The varying width of the channel 704 is based at least in part on a number of poles of the traction motor 102.

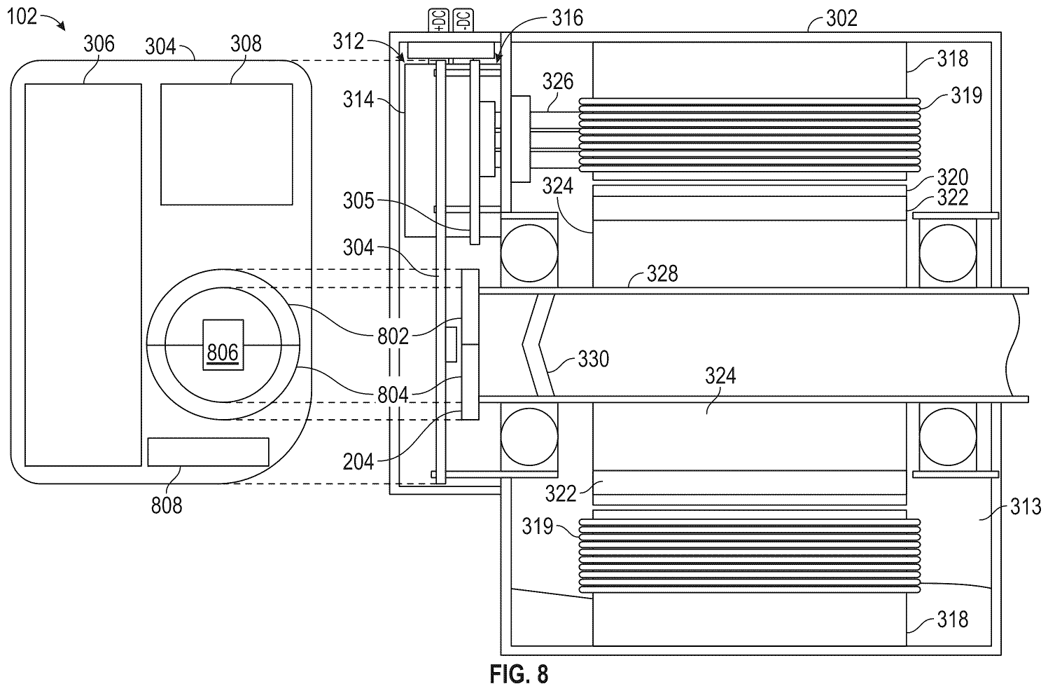

FIG. 8 illustrates a detailed view of components within the traction motor 102 according to an embodiment. In FIG. 8, the position of the shaft is determined using a magnetoresistive sensor technology.

As shown in FIG. 8, the target 204 is magnetized and/or includes a magnetic portion. For example, the target 204 is a magnet having a north pole (magnet (N) 802) and a south pole (magnet(S) 804), enabling an ASIC 806 (or other suitable circuitry) to determine the position of the shaft 328 based at least in part on the north pole and the south pole. It should be appreciated that other magnet arrangements are possible. For example, the target 204 can include a magnet having two north poles and two south poles arranged in a north/south/north/south configuration. As the target 204 rotates, the magnetic poles move relative to the ASIC 806, which the ASIC 806 can sense and use to determine the position of the shaft 328. That is, the ASIC 806 measure resistivity on its circuitry to detect a position of the shaft 328. The PCB 304 can include the ASIC 806 and ASIC support 808. The ASIC support 808 includes circuitry for supporting functions of the ASIC 806. The ASIC 806 is the integrated circuit responsible for determining the rotor position, while the ASIC support 808 is the supporting hardware for the ASIC 806, such as filters, power, and general interface connections to the microcontroller 306. According to one or more embodiments, the ASIC 806 and the ASIC support 808 can be combined into a single, integrated component.

According to one or more embodiments, various magnetoresistive sensor technologies can be used, such as one or more of an anisotropic magnetoresistance effect sensor (AMR), a giant magnetoresistance effect sensor (GMR), a tunnel magnetoresistance effect sensor (TMR), a circular vertical hall effect sensor (CVH), and/or the like, including combinations and/or multiples thereof. That is, the ASIC 806 can be or can include one or more of an AMR, a GMR, a TMR, a CVH, and/or the like, including combinations and/or multiples thereof.

One or more embodiments described herein is compatible with various motor topologies and can be implemented in both axial and radial configurations. This versatility allows for broader application across different types of electric vehicles and drive units, providing a flexible solution that can be adapted to meet specific design and performance requirements.

One or more embodiments provide improved packaging for the inductive position sensor (IPS) when integrated into an axially placed inverter, reduce the number of PCBs for the drive unit by placing IPS excitation coils onto the existing inverter control PCBs, lower complexity of the position sensor as compared with traditional resolvers by using fewer daughter boards and connectors, provide compatibility with various motor types if the inverter is axially paced at the end of the traction motor, provides the opportunity to implement redundant position sensors to satisfy ASIL-D safety specifications, and provide the ability to integrate AMR, GMR, TMR, or CVH sensing. Although CVH is not technically a magneto-resistive sensor, the CVH sensing uses the Hall effect to observe differences in voltage across pins that are laid out in a circle due to the orientation of a magnetic field and thus can be considered along with other magneto-resistive sensors according to one or more embodiments described herein.

Overall, the technical benefits of the various embodiments described herein contribute to a more efficient, reliable, and cost-effective traction motor system, enhancing the performance and functionality of electric vehicles and/or other devices or vehicles that use such drive units.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on”another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A vehicle comprising:
drive unit comprising:
a printed circuit board (PCB) comprising a coil assembly;
a rotor assembly connected to a shaft, the shaft having a target; and
circuitry electrically coupled to the coil assembly, the circuitry transmitting an electromagnetic field from the coil assembly to the target on the shaft, receiving a reflected electromagnetic field at the coil assembly from the target on the shaft, and determining a position of the shaft based at least in part on the reflected electromagnetic field.

2. The vehicle of claim 1, wherein the coil assembly comprises a transmitting coil and receiving coils.

3. The vehicle of claim 2, wherein the receiving coils comprise a receiving sine coil and a receiving cosine coil.

4. The vehicle of claim 2, wherein the transmitting coil and the receiving coils are disposed on a first layer of the PCB and a second layer of the PCB.

5. The vehicle of claim 2, wherein the coil assembly comprises a first transmitting coil associated with a first set of receiving coils, and a second transmitting coil associated with a second set of receiving coils.

6. The vehicle of claim 5, wherein the first transmitting coil and the first set of receiving coils are disposed on a first layer of the PCB and a second layer of the PCB, and wherein the second transmitting coil and the second set of receiving coils are disposed on a third layer of the PCB and a fourth layer of the PCB.

7. The vehicle of claim 1, wherein the circuitry comprises an application-specific integrated circuit.

8. The vehicle of claim 1, wherein the circuitry is disposed on the PCB.

9. The vehicle of claim 1, wherein the circuitry is disposed on a second PCB, the second PCB being a flexible PCB being substantially circular and defining an interior portion, wherein the target is positioned within the interior portion.

10. A drive unit for a vehicle, the drive unit comprising:
a printed circuit board (PCB) comprising a position sensor;
a rotor assembly connected to a shaft, the shaft having a target; and
circuitry electrically coupled to the position sensor, the circuitry determining a position of the shaft using the target.

11. The drive unit of claim 10, wherein the target comprises a disk affixed to an end of the shaft, wherein the disk comprises a first side affixed to the end of the shaft, a second side, and an edge between a first circumference of the first side and a second circumference of the second side, wherein the edge comprises a channel having a varying width based at least in part on a number of poles of the drive unit.

12. The drive unit of claim 11, wherein the circuitry determines the position of the shaft based at least in part on the channel.

13. The drive unit of claim 10, wherein the target comprises a magnet having a north pole and a south pole.

14. The drive unit of claim 13, wherein the circuitry comprises the position of the shaft based at least in part on the north pole and the south pole.

15. The drive unit of claim 10, wherein the position sensor is a magnetoresistive sensor.

16. The drive unit of claim 10, wherein the position sensor is an anisotropic magnetoresistance effect sensor.

17. The drive unit of claim 10, wherein the position sensor is a giant magnetoresistance effect sensor.

18. The drive unit of claim 10, wherein the position sensor is a tunnel magnetoresistance effect sensor.

19. The drive unit of claim 10, wherein the position sensor is a circular vertical hall effect sensor.

20. A printed circuit board associated with a drive unit of a vehicle and being oriented substantially perpendicular to an axial direction of a shaft of the drive unit, the printed circuit board comprising:
a microcontroller;
a first application-specific integrated circuit;
a second application-specific integrated circuit; and
a plurality of layers,
wherein a first layer of the plurality of layers and a second layer of the plurality of layers comprise a first transmitting coil and a first set of receiving coils,
wherein a third layer of the plurality of layers and a fourth layer of the plurality of layers comprise a second transmitting coil and a second set of receiving coils,
wherein the first application-specific integrated circuit transmits a first electromagnetic field from the first transmitting coil to a target on the shaft, receives a first reflected electromagnetic field at the first set of receiving coils from the target on the shaft, and determines a first position of the shaft based at least in part on the first reflected electromagnetic field,
wherein the second application-specific integrated circuit transmits a second electromagnetic field from the second transmitting coil to the target on the shaft, receives a second reflected electromagnetic field at the second set of receiving coils from the target on the shaft, and determines a second position of the shaft based at least in part on the second reflected electromagnetic field, and
wherein the microcontroller determines a third position of the shaft based at least in part on the first position and the second position.
